(19) United States
(12) Patent Application Publication
(10) Pub. No.: US 2026/0156337 A1
(43) Pub. Date: Jun. 4, 2026

(54) IMAGING APPARATUS AND HEAT SOURCE COOLING METHOD IN IMAGING APPARATUS

(71) Applicant: Panasonic Intellectual Property Management Co., Ltd., Osaka (JP)

(72) Inventors: Ryogo OKUMURA, Osaka (JP); Norikazu KANEDA, Osaka (JP)

(73) Assignee: Panasonic Intellectual Property Management Co., Ltd., Osaka (JP)

(21) Appl. No.: 19/347,806

(22) Filed: Oct. 2, 2025

(30) Foreign Application Priority Data
Oct. 15, 2024 (JP) 2024-179995

(51) Int. Cl. H04N 23/52; H04N 23/51; H05K 7/20

(52) U.S. Cl. CPC H04N 23/52; H04N 23/51; H05K 7/20145; H05K 7/20154; H05K 7/20209; H05K 7/2039

(57) ABSTRACT

An imaging apparatus includes: a fan that operates to draw air through an intake port disposed on an outer surface of the imaging apparatus and to discharge the air through an exhaust port disposed on the outer surface; a first flow path member having a first flow path between the intake port and the fan; a second flow path member having a second flow path between the intake port and the fan; a third flow path member having a third flow path between the fan and the exhaust port; a first heat source that is cooled by the air in the second flow path; and a second heat source that is cooled by the air in the third flow path.

### TECHNICAL FIELD

The present disclosure relates to an imaging apparatus and a method for cooling a heat source in the imaging apparatus.

### BACKGROUND ART

Up until now, imaging apparatuses having a cooling structure for cooling a heat source such as an IC have been known (see, e.g., Patent document 1).

The imaging apparatus of Patent document 1 has an intake aperture and an exhaust aperture disposed in a housing, and a fan that acts to draw air through the intake aperture and expel it through the exhaust aperture. In this configuration, the intake aperture has a first intake aperture and a second intake aperture, a first electronic component is disposed in a first duct that communicates with the first intake aperture, and a second electronic component is disposed in a second duct that communicates with the second intake aperture, thereby cooling plural electronic components (heat sources).

### PATENT DOCUMENT

Patent Document 1: JP 2020-113889 A

### SUMMARY

However, there is a need to cool plural heat sources more efficiently.

An object of the present disclosure is to provide an imaging apparatus capable of efficiently cooling plural heat sources and a method for cooling heat sources in the imaging apparatus.

An imaging apparatus of this disclosure comprises: a fan that operates to draw air through an intake port disposed on an outer surface of the imaging apparatus and to discharge the air through an exhaust port disposed on the outer surface; a first flow path member having a first flow path between the intake port and the fan; a second flow path member having a second flow path between the intake port and the fan; a third flow path member having a third flow path between the fan and the exhaust port; a first heat source to be cooled by the air in the second flow path; and a second heat source to be cooled by the air in the third flow path.

A method for cooling a heat source in an imaging apparatus of this disclosure comprises: activating a fan to draw in air through an intake port disposed on an outer surface of the imaging apparatus and to discharge the air through an exhaust port disposed on the outer surface, thereby causing the air to flow through a first flow path between the intake port and the fan; causing the air to flow through a second flow path between the intake port and the fan, to cool a first heat source; and causing the air to flow through a third flow path between the fan and the exhaust port, to cool a second heat source.

According to the present disclosure, plural heat sources can be cooled more efficiently.

### BRIEF DESCRIPTION OF DRAWINGS

FIG. 1 is a perspective view of an imaging apparatus;

FIG. 2 is a perspective view of a cover and its surroundings;

FIG. 3 is a perspective view showing a state in which the cover is removed from the configuration of FIG. 2;

FIG. 4 is a perspective view showing a state in which a first support member is further removed from the configuration of FIG. 3;

FIG. 5 is a transverse cross-sectional view schematically showing a flow path configuration of FIGS. 3 and 4;

FIG. 6 is a diagram showing a more schematic view of the configuration of FIG. 5;

FIG. 7 is a schematic diagram showing a variant; and

FIG. 8 is a schematic diagram showing another variant.

### DETAILED DESCRIPTION

An embodiment will now be described in detail with reference to the accompanying drawings as appropriate. Note, however, that more detailed explanation than necessary may be omitted. For example, detailed explanation of well-known matters or duplicate explanation of substantially the same configuration may be omitted.

The applicant provides the accompanying drawings and the following description to enable those skilled in the art to fully understand the present disclosure, and does not intend for them to limit the subject matter defined in the claims.

### EMBODIMENT

Hereinafter, an imaging apparatus and a heat source cooling method in the imaging apparatus according to this embodiment will be described with reference to the drawings.

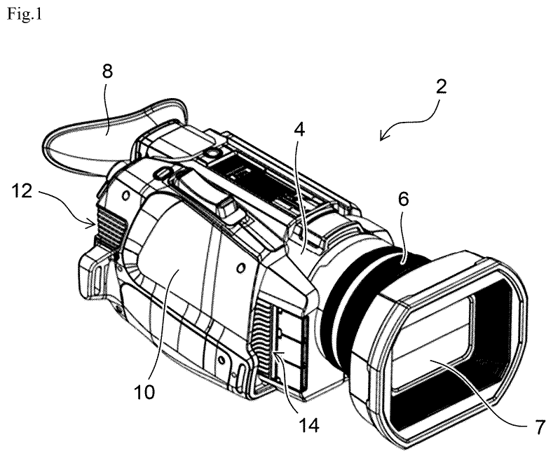

FIG. 1 is a perspective view showing an imaging apparatus 2 of this embodiment. As shown in FIG. 1, the imaging apparatus 2 of this embodiment includes a main body 4, a lens barrel 6, a viewfinder 8, an image pickup (not shown) having an image pickup element that converts light into an electrical signal, and a controller (not shown) that controls these.

The main body 4 is a part that makes up the outer shell of the imaging apparatus 2. Various switches and the like are disposed on the exterior of the main body 4, and various members such as the image pickup, the controller, and a fan are built in the main body 4. The lens barrel 6 is a member that holds a lens 7 and is disposed at the front (subject side) of the main body 4. The viewfinder 8 is a member that allows the imaging status to be confirmed by an image displayed on a display (not shown) based on information acquired by the image pickup (not shown). If the lens 7 side of the main body 4 is considered to be the front, the viewfinder 8 is disposed at the rear of the main body 4. Note that the position of the viewfinder 8 may be other than the rear of the main body 4, for example, on the lateral side of the main body 4. Further, the configuration of the viewfinder 8 may include, for example, a configuration in which the viewfinder 8 has an eyepiece or an eyepiece lens, a configuration in which a display (e.g., an LCD) is disposed instead of the viewfinder 8, a configuration in which the content being captured is displayed on external equipment (e.g., a PC, mobile phone, smartphone, tablet terminal, etc.) having a display via a wired or wireless communication interface, or a configuration in which these are combined.

As shown in FIG. 1, a cover 10 is disposed as a member that constitutes the outer surface of the main body 4. As a cooling structure for cooling the heat source, an intake port 12 is formed at the rear of the cover 10, and an exhaust port 14 is formed at the front of the cover 10.

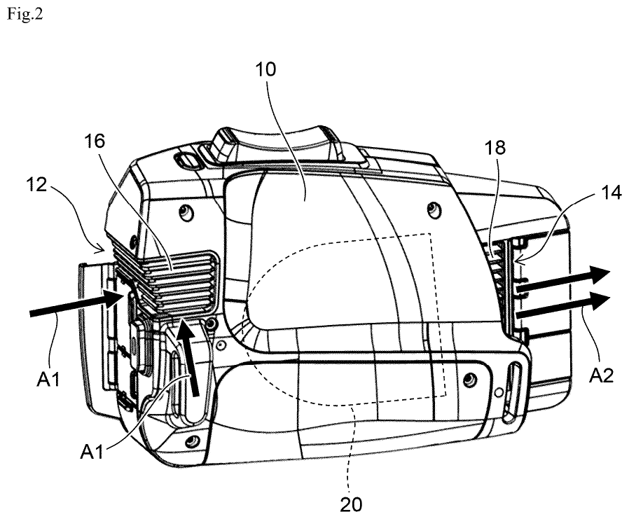

FIG. 2 is a perspective view of the cover 10 and its surroundings.

As shown in FIG. 2, an intake block 16 and an exhaust block 18 are attached to the cover 10. The intake block 16 is a block member having the intake port 12, and the exhaust block 18 is a block member having the exhaust port 14.

A fan 20 is built in the inside of the cover 10. In FIG. 2, the fan 20 is indicated schematically by a dotted line.

The fan 20 operates to generate a flow of air for cooling the heat source. When the fan 20 operates, air is drawn in through the intake port 12 (arrow A1), passes through the interior of the imaging apparatus 2, and is exhausted from the exhaust port 14 (arrow A2).

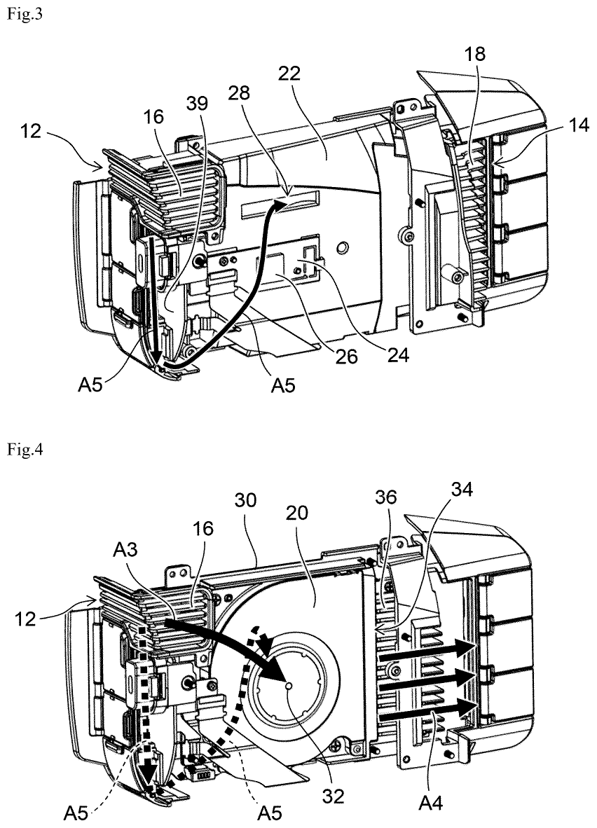

The imaging apparatus 2 of this embodiment has a structure for efficiently cooling a plurality of heat sources, such as ICs and communication modules, built in. This structure will be described with reference to FIG. 3 and subsequent drawings.

FIG. 3 is a perspective view showing the configuration shown in FIG. 2 with the cover 10 removed.

As shown in FIG. 3, a first support member 22 is disposed inside the cover 10.

The first support member 22 is a member that supports a substrate 24 and a communication module 26. The substrate 24 is a substrate on which the communication module 26 is mounted. The communication module 26 is a module with communication functions, and operates while mounted on the substrate 24. By attaching the substrate 24 to the first support member 22, the substrate 24 and the communication module 26 are integrally supported by the first support member 22. The first support member 22 in this embodiment has a plate-like shape.

In order to improve the communication function of the communication module 26, it is preferable to place the communication module 26 as far outside as possible from the imaging apparatus 2 without shielding it with a metal plate or the like. In this embodiment, only the cover 10 is located outside the communication module 26, and the cover 10 is made of resin and has low radio wave shielding function. This can improve the communication function of the communication module 26.

As shown in FIG. 3, an opening 28 is formed in the first support member 22. The opening 28 is an aperture for generating a flow of air that cools the communication module 26.

FIG. 4 is a perspective view showing a state in which the first support member 22 is further removed from the configuration shown in FIG. 3.

As shown in FIG. 4, the fan 20 (FIG. 2) and a second support member 30 are disposed inside the first support member 22. The second support member 30 is a plate-shaped member that supports the fan 20.

The fan 20 has a fan inlet 32 and a fan outlet 34.

The fan inlet 32 is an opening through which air is drawn into the interior of the fan 20, and the fan outlet 34 is an opening through which the air drawn into the interior of the fan 20 is discharged.

A heat dissipation member 36 is disposed at a position facing the fan outlet 34. The heat dissipation member 36 is a member to which a plurality of heat sources, such as an IC 38 (described later), are thermally connected, and may also be referred to as a “heat sink.”

When the fan 20 operates, the air drawn in through the intake port 12 flows mainly toward the fan inlet 32 of the fan 20 (arrow A3) and is discharged from the fan outlet 34 (arrow A4). The air discharged from the fan outlet 34 flows along the surface of the heat dissipation member 36, thereby cooling the heat dissipation member 36 and cooling a heat source such as the IC 38 thermally connected to the heat dissipation member 36.

As shown in FIG. 3, another flow path is formed outside the first support member 22, i.e., in the space between the first support member 22 and the cover 10. A portion of the air drawn in through the intake port 12 branches downward and flows along the plate-like member 39, then flows along the outer surface of the first support member 22 and enters the opening 28 (arrow A5). This air flows along the surface of the communication module 26, thereby cooling the communication module 26.

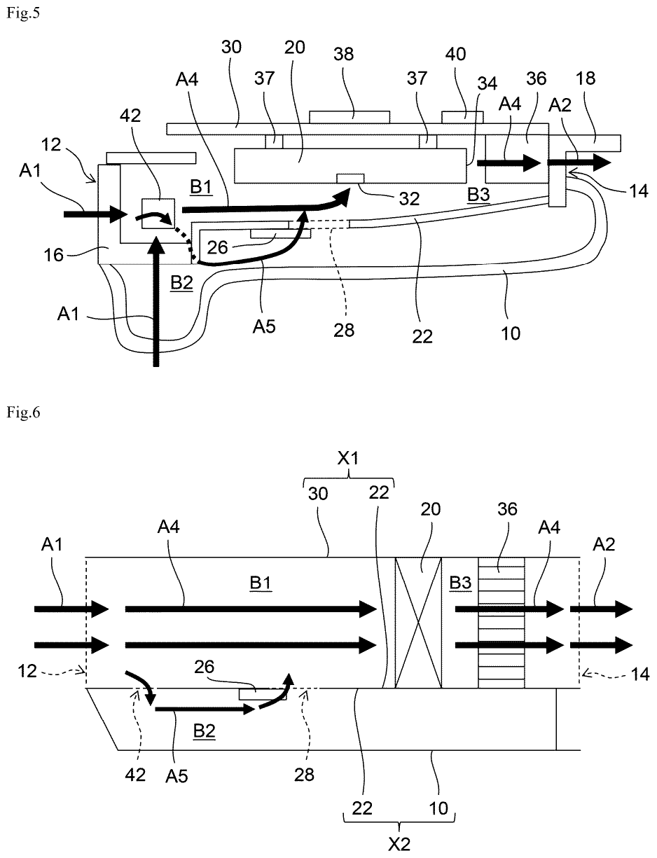

The flow path configurations shown in FIGS. 3 and 4 will be described with reference to FIGS. 5 and 6.

FIG. 5 is a transverse cross-sectional view showing the flow channel configuration shown in FIGS. 3 and 4, and FIG. 6 is a diagram showing the configuration of FIG. 5 in a more simplified manner.

As shown in FIG. 5, the IC 38 and a memory 40 are disposed as heat sources thermally connected to the heat dissipation member 36. Among the heat sources built in the imaging apparatus 2, the IC 38 generates the most heat.

In this embodiment, both the IC 38 and the memory 40 are attached to the back surface of the second support member 30. The second support member 30 in this embodiment is made of a material with high thermal conductivity, such as metal, and functions as a heat transfer member that transfers heat. Note that the IC 38 and the memory 40 may be attached to the back surface of the second support member 30 via a heat transfer member.

In this specification, the term “heat transfer member” refers to a member (e.g., a metal plate or a graphite sheet) made of a material with high thermal conductivity such as metal, and does not include a member made of a material with low thermal conductivity such as resin. The heat transfer member includes a thermal interface material (TIM).

The fan 20 is not directly attached to the second support member 30, but is indirectly attached via an intermediate attachment member 37. Heat from the IC 38 and memory 40 is transferred mainly to the heat dissipation member 36, not to the fan 20.

The heat dissipation member 36 may be thermally connected to a heat source (for example, a storage medium) other than the IC 38 and the memory 40.

As shown in FIGS. 5 and 6, air flowing in through the intake port 12 flows through a first flow path B1. The first flow path B1 is a flow path that extends from the intake port 12 to the fan inlet 32 and is defined by at least the first support member 22 and the second support member 30. The first support member 22 and the second support member 30 are first flow path members that define the first flow path B1.

An opening 42 is disposed midway along the first flow path B1. The opening 42 allows a portion of the air flowing through the first flow path B1 to flow into a second flow path B2. The second flow path B2 is a flow path extending from the opening 42 to the opening 28 and is defined by at least the first support member 22 and the cover 10. The first support member 22 and the cover 10 are second flow path members that define the second flow path B2.

The second flow path B2 in this embodiment is a flow path that branches off from the first flow path B1 midway and then merges with the first flow path B1 again.

As shown in FIGS. 5 and 6, the communication module 26 serving as a heat source is disposed in the second flow path B2. In contrast, no heat source or heat dissipation member thermally connected to the heat source is disposed in the first flow path B1. With this arrangement, the communication module 26 is cooled by the airflow through the second flow path B2, while the airflow through the first flow path B1 can be maintained at a low temperature (approximately room temperature). Therefore, even if the airflow through the second flow path B2 that has absorbed heat from the communication module 26 merges with the first flow path B1, an overall temperature increase can be suppressed, and low-temperature air can be sent to the fan 20.

Furthermore, in this embodiment, the area of the upstream opening 42 of the second flow path B2 is smaller than the area of the downstream opening 28 thereof.

By reducing the size of the upstream opening 42, it becomes easier to control the amount of airflow flowing from the first flow path B1 to the second flow path B2 to be relatively small. Because the communication module 26 generates less heat than the IC 38, by keeping the amount of airflow through the second flow path B2 small, the communication module 26 can be cooled with an appropriate amount of airflow.

By enlarging the downstream opening 28, it becomes easier to control the wind pressure at the opening 42 to be higher than the wind pressure at the opening 28. This makes it possible to stably generate a flow from the opening 42 toward the opening 28 and to suppress backflow.

Air discharged from the fan outlet 34 flows through a third flow path B3. The third flow path B3 is a flow path that extends from the fan outlet 34 to the exhaust port 14 and is defined by at least the first support member 22 and the second support member 30. The first support member 22 and the second support member 30 are third flow path members that define the third flow path B3.

The heat dissipation member 36 is disposed in the third flow path B3. As described above, the air taken in by the fan 20 is relatively low temperature, so the heat dissipation member 36 can be cooled by a large volume of low-temperature air. This allows for strong cooling of the IC 38 and memory 40, which generate a large amount of heat.

In the imaging apparatus 2 having the above configuration and functions, when the fan 20 is operated, an air flow is generated in which air is drawn in through the intake port 12 and expelled from the exhaust port 14. In this air flow, air flows through the first flow path B1 and the second flow path B2 between the intake port 12 and the fan 20, and air flows through the third flow path B3 between the fan 20 and the exhaust port 14. Here, the air through the first flow path B1 does not cool the heat source, the air through the second flow path B2 cools the communication module 26 (first heat source), and the air through the third flow path B3 cools the IC 38 and the memory 40 (second heat source). This makes it possible to efficiently cool each heat source according to the difference in the heat generation amount of each heat source.

### (Actions and Effects)

As described above, the imaging apparatus 2 of this embodiment includes the fan 20 that operates to draw in air through the intake port 12 disposed on the outer surface of the imaging apparatus 2 and exhaust the air from the exhaust port 14 disposed on the outer surface, a first flow path member (e.g., the first support member 22, the second support member 30) having the first flow path B1 between the intake port 12 and the fan 20, a second flow path member (e.g., the first support member 22, the cover 10) having the second flow path B2 between the intake port 12 and the fan 20, a third flow path member (e.g., the first support member 22, the second support member 30) having the third flow path B3 between the fan 20 and the exhaust port 14, a first heat source (e.g., the communication module 26) that is cooled by the air in the second flow path B2, and a second heat source (e.g., the IC 38) that is cooled by the air in the third flow path B3.

This configuration enables a plurality of heat sources to be efficiently cooled.

In the imaging apparatus 2 of this embodiment, a heat source or a heat dissipation member 36 thermally connected to a heat source is not disposed in the first flow path B1. With this configuration, by sending low-temperature air from the first flow path B1 to the third flow path B3, the cooling effect of the second heat source can be improved.

In the imaging apparatus 2 of this embodiment, the first heat source (for example, the communication module 26) is disposed in the second flow path B2. With this configuration, the first heat source can be directly cooled, thereby enhancing the cooling effect of the first heat source.

The imaging apparatus 2 of this embodiment further includes a heat dissipation member 36 thermally connected to a second heat source (e.g., the IC 38), and the heat dissipation member 36 is disposed in the third flow path B3. With this configuration, the second heat source can be indirectly cooled via the heat dissipation member 36.

In the imaging apparatus 2 of this embodiment, a plurality of the second heat sources (e.g., the IC 38, the memory 40) are thermally connected to the heat dissipation member 36. With this configuration, the plurality of the second heat sources can be efficiently cooled by the high-volume air flowing through the third flow path B3.

Furthermore, in the imaging apparatus 2 of this embodiment, the first heat source includes the communication module 26. With this configuration, the communication module 26, which generates less heat than the IC 38 and the like, can be efficiently cooled by the air flowing through the second flow path B2.

Furthermore, in the imaging apparatus 2 of this embodiment, the second flow path member having the second flow path B2 includes the cover 10 that forms the outer surface, and the first support member 22 that is disposed inside the cover 10 to support the first heat source. With this configuration, by disposing the first heat source including the communication module 26 close to the outer surface of the imaging apparatus 2, the communication function of the communication module 26 can be improved.

In the imaging apparatus 2 of this embodiment, the second heat source includes the IC 38. With this configuration, the second heat source, which generates a large amount of heat, can be efficiently cooled by the airflow through the third flow path B3, which has a large air volume. The second heat source may include an image pickup (not shown) or may be thermally connected to the image pickup.

Furthermore, in the imaging apparatus 2 of this embodiment, the second heat source (e.g., the IC 38) generates more heat than the first heat source (e.g., the communication module 26). With this configuration, the second heat source, which generates a large amount of heat, can be efficiently cooled by the airflow through the third flow path B3, which has a large airflow rate.

In the imaging apparatus 2 of this embodiment, the second flow path B2 branches from the first flow path B1 and then merges with the first flow path B1. With this configuration, the air volume of the second flow path B2 can be easily adjusted, for example, by relatively reducing the air volume of the second flow path B2.

Furthermore, in the imaging apparatus 2 of this embodiment, the second flow path member having the second flow path B2 has the upstream opening 42 (first opening) and the downstream opening 28 (second opening), the openings 42 and 28 communicating with the first flow path B1 of the first flow path member, and the area of the opening 42 is smaller than the area of the opening 28. With this configuration, by narrowing the opening 42, the amount of air flowing through the second flow path B2 is relatively small, while by widening the opening 28, a pressure difference is more likely to occur between the opening 42 and the opening 28, allowing air to flow stably through the second flow path B2.

As described above, the heat source cooling method for the imaging apparatus 2 of this embodiment includes activating the fan 20 to draw in air through the intake port 12 disposed on the outer surface of the imaging apparatus 2 and to discharge the air through the exhaust port 14 disposed on the outer surface, thereby causing the air to flow through the first flow path B1 between the intake port 12 and the fan 20, causing the air to flow through the second flow path B2 between the intake port 12 and the fan 20 to cool the first heat source (e.g., the communication module 26), and causing the air to flow through the third flow path B3 between the fan 20 and the exhaust port 14 to cool the second heat source (e.g., the IC 38).

According to this method, plural heat sources can be cooled efficiently. As long as this method is achieved, the positions of the intake port 12 and the exhaust port 14 in the image capture apparatus 2 do not matter. For example, the intake port 12 and the exhaust port 14 may be arranged in opposite directions. Furthermore, while the intake port 12 and the exhaust port 14 are arranged in the front and rear of the image capture apparatus 2 in the above-described embodiment, they may also be arranged in any physically possible direction, such as up and down, left and right, etc.

### (Other Embodiments)

The present disclosure is not limited to the above-described embodiment, and various embodiments are conceivable.

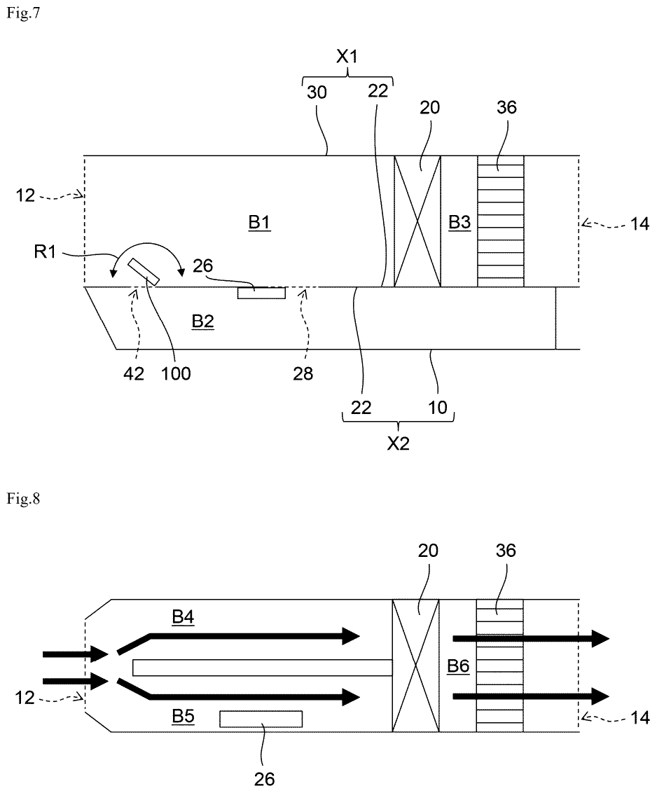

In the above embodiment, the case has been described where the volume of air flowing through each of the three flow paths B1 to B3 is constant, but this is not limitative and an “air volume change member” that can change the volume of air may be disposed. For example, in the example shown in FIG. 7, an air volume change member 100 is disposed that can change the volume of air flowing through the second flow path B2.

The air volume change member 100 shown in FIG. 7 is disposed adjacent to the opening 42, which is the inlet of the second flow path B2, and is movable to change the amount of air flowing into the opening 42. Specifically, the air volume change member 100 is movable between a first position where the flow rate of air flowing into the second flow path B2 is relatively increased, and a second position where the flow rate of air flowing into the second flow path B2 is relatively decreased. The movement of the air volume change member 100 may be electrically controlled by a controller (not shown), or may be controlled by any other method.

According to this configuration, by controlling the position of the air volume change member 100, the flow rate of air flowing into the second flow path B2 can be changed depending on the usage state of the communication module 26, thereby more efficiently cooling plural heat sources. For example, the position of the air volume change member 100 may be controlled so that the flow rate of air flowing into the second flow path B2 is relatively small when the communication module 26 is not in use (when the amount of heat generated is low), and the flow rate is relatively large when the communication module 26 is in use (when the amount of heat generated is high).

In the above embodiment, the second flow path B2 is a flow path that branches off from the first flow path B1 and then rejoins the first flow path B1, but the present invention is not limited to this. For example, as shown in FIG. 8, a first flow path B4 and a second flow path B5 may extend parallel to each other from the intake port 12 to the fan 20. Air drawn into the fan 20 is blown toward a third flow path B6 and flows along the surface of the heat dissipation member 36 connected to a heat source such as the IC 38 (not shown).

Therefore, the members shown in the accompanying drawings and detailed description may include not only essential members for solving the problem, but also members that are not essential for solving the problem in order to exemplify the above technique. Hence, the fact that these non-essential members are shown in the accompanying drawings or detailed description should not be interpreted as immediately indicating that these non-essential members are essential.

Furthermore, since the above-described embodiments are intended to exemplify the technique of the present disclosure, various modifications, substitutions, additions, omissions, etc. may be made within the scope of the claims or their equivalents.

The present disclosure is widely applicable to imaging apparatuses.
2 imaging apparatus
10 cover (second flow path member)
12 intake port
14 exhaust port
16 intake block
18 exhaust block
20 fan
22 first support member (first flow path member, second flow path member, third flow path member)
24 substrate
26 communication module
28 opening
30 second support member (first flow path member, third flow path member)
32 fan inlet
34 fan outlet
36 heat dissipation member
38 IC
40 memory
42 opening
100 air volume changing member
B1 first flow path
B2 second flow path
B3 third flow path
B4 first flow path
B5 second flow path
B6 third flow path

What is claimed is

1. An imaging apparatus comprising:
a fan that operates to draw air through an intake port disposed on an outer surface of the imaging apparatus and to discharge the air through an exhaust port disposed on the outer surface;
a first flow path member having a first flow path between the intake port and the fan;
a second flow path member having a second flow path between the intake port and the fan;
a third flow path member having a third flow path between the fan and the exhaust port;
a first heat source that is cooled by the air in the second flow path; and
a second heat source that is cooled by the air in the third flow path.

2. The imaging apparatus according to claim 1, wherein
a heat source or a heat dissipation member thermally connected to a heat source is not disposed in the first flow path.

3. The imaging apparatus according to claim 1, wherein
the first heat source is disposed in the second flow path.

4. The imaging apparatus according to claim 1, further comprising:
a heat dissipation member thermally connected to the second heat source, wherein
the heat dissipation member is disposed in the third flow path.

5. The imaging apparatus according to claim 4, wherein a plurality of the second heat sources are thermally connected to the heat dissipation member.

6. The imaging apparatus according to claim 1, wherein
the first heat source includes a communication module.

7. The imaging apparatus according to claim 1, wherein
the second flow path member comprises:
a cover that forms the outer surface; and
a support member that is disposed inside the cover to support the first heat source.

8. The imaging apparatus according to claim 1, wherein
the second heat source includes an IC.

9. The imaging apparatus according to claim 1, wherein
the second heat source generates more heat than the first heat source.

10. The imaging apparatus according to claim 1, wherein
the second flow path branches from the first flow path and then merges with the first flow path.

11. The imaging apparatus according to claim 10, wherein
the second flow path member has a first opening on an upstream side and a second opening on a downstream side, the first and second openings communicating with the first flow path of the first flow path member, and wherein
an area of the first opening is smaller than an area of the second opening.

12. The imaging apparatus according to claim 1, further comprising:
an air volume change member that operates to change the volume of air flowing through the second flow path.

13. A method for cooling a heat source in an imaging apparatus, comprising:
activating a fan to draw in air through an intake port disposed on an outer surface of the imaging apparatus and to discharge the air through an exhaust port disposed on the outer surface, thereby
causing the air to flow through a first flow path between the intake port and the fan;
causing the air to flow through a second flow path between the intake port and the fan, to cool a first heat source; and
causing the air to flow through a third flow path between the fan and the exhaust port, to cool a second heat source.
